(19) United States
(12) Patent Application Publication
(10) Pub. No.: US 2003/0189176 A1
(43) Pub. Date: Oct. 9, 2003

(54) Method and device for generating euv radiation

(76) Inventors: Boris Chichkov, Hannover (DE); Andr?eacute; Egbert, Haste (DE)

Correspondence Address: Robert W Becker & Associates, Suite B, 707 Highway East, Tijeras, NM, 87059-7382, US

(21) Appl. No.: 10/276,104

(22) PCT Filed: Mar. 13, 2002
(86) PCT No.: PCT/EP02/02772

(30) Foreign Application Priority Data
Mar. 15, 2001 (DE) 101 13 064.3

(51) Int. Cl. H01J 37/141; G21G 5/00; G01J 1/00

(52) U.S. Cl. 250/396 ML; 250/492.3; 250/504 R

(57) ABSTRACT

The invention relates to a method for generating EUV radiation. Laser pulses are directed onto photoelectric transducer means (10), which generate pulses of electrically charged particles (6) as a result of the action of the laser pulses. The electrically charged particles are accelerated in an electric field and directed onto a target (4), in such a way that the target generates a plasma, which emits EUV radiation, as a result of the action of the electrically charged particles.

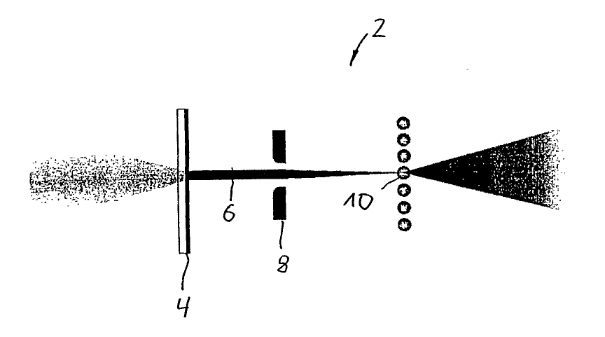

The invention relates to a method of the type mentioned in the preamble of claim 1, and a device of the type mentioned in the preamble of claim 14, for the generation of UV radiation, especially EUV radiation.

During the manufacture of integrated circuits, to a large extent methods for the optical projections lithography are utilized in order to form, upon the surface of semiconductor wafers, patterns that define the integrated circuits. In so doing, the dimensions of the projected pattern are primarily a function of the wavelength of the radiation used for the projection, whereby the shorter the wavelengths of the radiation used, the finer can be the patterns that are formed.

In order in contrast to the known methods for the optical projections lithography to achieve an extensive miniaturization of semiconductor circuits, it is known, during the lithography, to use EUV (Extreme Ultra-Violet) radiation having a wavelength from 11 to 14 nm.

From the publications “EUV Lithography—The Successor to Optical Lithography?”, Intel Technology Journal Q3 '98, and “Extreme Ultraviolet Lithography”, J. Vac. Sci Technol. B 16 (6), November/December 1998, methods are known for the generation of EUV radiation according to which laser pulses are used for the production of a plasma that emits the EUV radiation. With the known methods, laser pulses having high repetition rates are directed upon a target that, for example, is comprised of xenon, whereby during irradiation of the target a plasma results that emits the EUV radiation. The EUV radiation generated in this manner can then, for example, be utilized in the EUV lithography during the manufacture of semiconductor circuits.

A drawback of the known methods is that the laser pulses must have a high energy so that a plasma that emits EUV radiation can be produced in the desired manner. The high power lasers required during the known methods are therefore complicated and expensive, so that it is not possible to have an economical mass production of semiconductor circuits.

The object of the invention is to provide a method and a device for the generation of UV radiation, especially EUV radiation, according to which the generation of UV radiation, especially EUV radiation, is possible with straightforward means and hence an economical manner.

With regard to the method, this object is realized by the teaching of claim 1, and with regard to the device is realized by the teaching of claim 14.

The invention proceeds from the recognition that an economical use of lasers during a production of a plasma that emits EUV radiation is possible only if simple and economical lasers are utilized, whereby, however, the power of such lasers is not sufficient for the production of the plasma. Proceeding from this recognition, the basic concept of the invention is that the laser pulses not be directed directly upon the target, but rather to first reinforce the energy of the laser pulses such that a plasma that emits EUV radiation can be produced in the desired manner. To increase the energy of the laser pulses, the inventive teaching proposes that the laser pulses be directed upon photoelectric transducer means, that, under the effect of the laser pulses, produce pulses of electrically charged particles. These electrically charged particles can then, in a straightforward manner, be accelerated in an electrical field to such an extent that during a subsequent striking or impingement of the particles onto the target, a sufficient energy is available in order to produce a plasma that emits EUV radiation.

The increase of the energy of the particles, in this connection, is limited only by the intensity of the electrical field, so that with an appropriate selection of the intensity or strength of the field, the energy of the particles can be readily increased to such an extent that during the subsequent impingement upon the target, a plasma is produced that emits EUV radiation.

With the appropriate selection of the strength of the electrical field, it is thus possible to use lasers having a relatively low power, which are simple and economical, so that the inventive teaching enables an economical use of lasers during the generation of EUV radiation.

The inventive method can be used everywhere that UV radiation, especially EUV radiation, is required. The inventive method is particularly well suited for use in the EUV lithography.

In principle, any desired electrically charged particles could be used. Expediently, however, the electrically charged particles are electrons, whereby pursuant to a further development the photoelectric transducer means have at least one photocathode that upon irradiation with laser pulses emits pulses of electrons. Such photocathodes are economical, so that pursuant to this further development the inventive method can be carried out particularly easily and hence economically.

To increase the energy of the electrons, with the aforementioned embodiment it is expedient that for the acceleration of the electrons an anode is used to which is applied a high voltage. In this connection, the degree of increase of energy of the electrons until they impinge upon the target is merely a function of the value of the applied high voltage.

With the aforementioned embodiment, the anode is expediently embodied in an essentially ring-shaped or annular configuration, so that the electrons pass through the opening in the anode and in so doing are accelerated. This enables in a particularly simple manner for the electrons to be directed upon the target, which in the direction of radiation of the electron beam is disposed downstream of the anode.

In order to concentrate the energy of the electrically charged particles upon a spatially limited portion of the target, it is expedient to focus the electrically charged particles upon the target.

Pursuant to a further development of the aforementioned embodiment, the electrically charged particles are focused via at least one electromagnetic optics mechanism. Such electromagnetic optics can be realized in a straightforward and hence economical manner, so that the inventive method is easy and hence economical to carry out.

The target can be formed by any desired target that upon irradiation with electrically charged particles emits UV radiation, especially EUV radiation. The target is expediently provided with liquid droplets, whereby pursuant to a further development of this embodiment the liquid is xenon or water. With the aforementioned embodiments, no contaminations (debris) occur, which could occur with a target that is comprised of solid bodies.

Pursuant to a further development, the target is a cluster target.

The plasma is expediently produced in a vacuum.

Pursuant to a further development of the inventive method, laser pulses having a high repetition rate of at least approximately 1000 Hz are used.

Pursuant to another further development, the target is a highly repetitive target.

Further developments of the inventive device are provided in the dependent claims 15 to 23.

The invention will be described in greater detail subsequently with the aid of the accompanying drawing, which represents one embodiment of an inventive device.

The single figure of the drawing shows an inventive device 2 for carrying out an inventive method for generating EUV radiation. The device 2 is provided with a laser, which is not illustrated in the drawing, and which produces laser pulses having a repetition rate of at least approximately 1000 Hz, and directs them onto photoelectric transducer means in the form of a photocathode 4. Under the effect of the laser pulses, pulses of electrons are released from the photocathode 4 and move, in the form of an electron beam 6, to a ring-shaped or annular anode 8. To accelerate the electrons, a high voltage is applied to the anode 8. In the electrical field that is formed between the photocathode 4 and the anode 8, the electrons are accelerated in conformity with the applied high voltage, so that their energy is greatly increased. With this embodiment, the high voltage is selected such that the energy of the electron pulses, after the acceleration in the electrical field, is greater by a factor of 10³ than the energy of the laser pulses produced by the laser.

Provided in the direction of radiation of the electron beam 6, downstream from the anode 8, are means, which are not illustrated in the drawing, for the focusing of the electron beam 6; such means can be formed, for example, by electro-magnetic optics. The electromagnetic optics focus the electron beam 6 onto a target, which in this embodiment is formed by a highly repetitive micro-droplet target that is comprised of xenon droplets 10.

When the electrons impinge upon the xenon droplets 10, a highly charged plasma is produced that produces the EUV radation in a wavelength range of 11 to 14 nm.

Due to the acceleration of the electrons in the electrical field, and the increase in their kinetic energy that is connected therewith, a high power is available for the irradiation of the xenon droplets 10 even if the laser, which irradiates the photocathode 4, has a relatively low power. With regard to the production of the electron beam for the irradiation of the xenon droplets, the inventive device 2 has a high stability, is compact in construction, and is simple and hence economical to manufacture.

1. Method for the generation of UV radiation, especially EUV radiation,
according to which laser pulses are used for the production of a plasma that emits UV radiation, especially EUV radiation,
characterized in,
that the laser pulses are directed onto photoelectric transducer means that under the effect of the laser pulses produce pulses of electrically charged particles, and
that the electrically charged particles are accelerated in an electrical field and are directed upon a target such that under the effect of the electrically charged particles the target produces a plasma that emits UV radiation, especially EUV radiation.

2. Method according to claim 1, characterized in that the electrically charged particles are electrons.

3. Method according to claim 1, characterized in that at least one photocathode is used as the photoelectric transducer means.

4. Method according to claims 2 and 3, characterized in that for the acceleration of the electrons an anode is used to which is applied a high voltage.

5. Method according to claim 4, characterized in that an essentially annular anode is used.

6. Method according to claim 1, characterized in that the electrically charged particles are focused upon the target.

7. Method according to claim 6, characterized in that the electrically charged particles are focused upon the target via at least one electromagnetic optics mechanism.

8. Method according to claim 1, characterized in that the target is provided with droplets of a liquid.

9. Method according to claim 8, characterized in that the liquid is water or xenon.

10. Method according to claim 1, characterized in that the target is a cluster target.

11. Method according to claim 1, characterized in that the plasma is produced in a vaccum.

12. Method according to claim 1, characterized in that the laser pulses have a high repetition rate of at least approximately 1000 Hz.

13. Method according to claim 1, characterized in that the target is a highly repetitive target.

14. Device for the generation of UV radiation, especially EUV radiation,
with a laser, which produces laser pulses for the production of a plasma that emits UV radiation, especially EUV radiation,
characterized in,
that the laser directs the laser pulses upon photoelectric transducer means that under the effect of the laser pulses produces pulses of electrically charged particles, and
that means are provided for the production of an electrical field that accelerates the electrically charged particles and directs them upon a target such that under the effect of the electrically charged particles the target produces a plasma that emits UV radiation, especially EUV radiation.

15. Device according to claim 14, characterized in that the electrically charged particles are electrons.

16. Device according to claim 14, characterized in that the photo electric transducer means is provided with at least one photocathode (4).

17. Device according to claim 15 and 16, characterized in that the means for the production of an electrical field is provided with an anode (8) to which is applied a high voltage.

18. Device according to claim 17, characterized in that the anode (8) has a ring-shaped or annular configuration.

19. Device according to claim 14, characterized by means for the focusing of the electrically charged particles upon the target.

20. Device according to claim 19, characterized in that the means for the focusing of the electrically charged particles are provided with at least one electromagnetic optics mechanism.

21. Device according to claim 14, characterized in that the target is provided with droplets (10) of a liquid.

22. Device according to claim 21, characterized in that the liquid is water or xenon.

23. Device according to claim 14, characterized in that the target is a cluster target.

24. Device according to claim 14, characterized in that the production of the plasma is effected in a vacuum.

25. Device according to claim 14, characterized in that the laser produces laser pulses having a high repetition rate of at least approximately 1000 Hz.

26. Device according to claim 14, characterized in that the target is a highly repetitive target.
